(19) United States
(12) Patent Application Publication
(10) Pub. No.: US 2002/0056877 A1
(43) Pub. Date: May 16, 2002

(54) METAL-OXIDE SEMICONDUCTOR TRANSISTOR THAT FUNCTIOINS AS A RECTIFIER

(76) Inventors: TINE-JUI LIU, TAI-CHUNG HSEIN (TW); YO-YI GONG, HSIN-CHU CITY (TW)

Correspondence Address: NAIPO (NORTH AMERICA INTERNATIONAL PATENT OFFICE), P.O. BOX 506, MERRIFIELD, VA, 22116, US

(21) Appl. No.: 09/479,935

(22) Filed: Jan. 10, 2000

(51) Int. Cl. H01L 23/62

(52) U.S. Cl. 257/355

(57) ABSTRACT

The present invention provides a metal-oxide semiconductor (MOS) transistor that functions as a rectifier positioned on a semiconductor wafer. The semiconductor wafer comprises a substrate, an active area defined on the substrate, a second P-type well positioned on the active area of the substrate and a field oxide layer positioned on the substrate which surrounds the active area. The MOS transistor comprises an N-type well positioned within a first predetermined area of the active area, a first P-type well positioned within the N-type well, a first N-type doped region positioned within the first P-type well, a second N-type doped region positioned within a second predetermined area of the active area, the second predetermined area not overlapping the first predetermined area, and a gate layer positioned on the substrate between the first N-type doped region and the second N-type doped region. The first N-type doped region and the second N-type doped region are separately used as a source and a drain of the MOS transistor. The gate layer comprises a gate dielectric layer positioned on the substrate and a gate electrode

### BACKGROUND OF THE INVENTION

1. Field of the Invention

The present invention relates to a metal-oxide semiconductor (MOS) transistor, and more particularly, to a MOS transistor that functions as a rectifier.

2. Description of the Prior Art

MOS transistor is a very important device of integrated circuits and which works as a switch of circuits more often than not. Nonetheless, since the embedded process is developed and integration is improved in integrated circuits processing, the MOS transistor that only functions as a switch gradually can not meet the requirements. Besides, the formation of a gate dielectric layer plays an important role in the MOS transistor process. If the gate dielectric layer is formed with undesirable quality, it will bring about breakdown and lower lifetime of the MOS transistor. Hence, how to form a MOS transistor with multi-function to integrate various devices of integrated circuits and promote the quality of the gate dielectric layer becomes an important issue at present.

Please refer to FIG. 1. FIG. 1 is a cross-sectional diagram of a MOS transistor 10 according to the prior art. The MOS transistor 10 is formed on a semiconductor wafer 12. The semiconductor wafer 12 comprises a substrate 14, an active area 18 defined on the substrate 14, a P-type well 16 positioned on the active area 16 of the substrate 14, and a field oxide layer 20 positioned on the substrate 14 which surrounds the active area 18. Furthermore, the semiconductor wafer 12 comprises a well pick-up 28 positioned within the P-type well 16. The MOS transistor 10 comprises a gate layer 22 positioned on the P-type well 16, a drain 24 and a source 26 separately positioned at two sides of the gate layer 22 within the P-type well 16. The gate layer 22 comprises a gate oxide layer 30 positioned on the P-type well 16 and a doped polysilicon layer 32 positioned on the gate oxide layer 30.

Please refer to FIG. 2 to FIG. 5. FIG. 2 to FIG. 5 are schematic diagrams of a method of forming the MOS transistor 10 shown in FIG. 1. As shown in FIG. 2, the semiconductor wafer 12 is used for forming the MOS transistor 10. First, as shown in FIG. 3, a dry oxidation method is employed to form the gate oxide layer 30 on the semiconductor wafer 12 and then the doped polysilicon layer 32 is formed on the gate oxide layer 30. Next, a photoresist layer 34 is formed on a predetermined area of the doped polysilicon layer 32 to define the position of the gate layer 22. As shown in FIG. 4, an etching process is then performed to remove the doped polysilicon layer 32 and the gate oxide layer 30 not covered by the photoresist layer 34. Thus, the doped polysilicon layer 32 and the gate oxide layer 30 remaining on the semiconductor wafer 12 form the gate layer 22. As shown in FIG. 5, after the photoresist layer 34 is removed, another photoresist layer 36 is then formed on another predetermined area of the semiconductor wafer 12 to define the position of the drain 24, the source 26 and the well pick-up 28. Next, an ion implantation process is performed to implant N-type dopants into the P-type well 16 so as to form the drain 24, the source 26 and the well pick-up 28. Finally, the photoresist layer 36 is removed and thus completes the MOS transistor 10 as shown in FIG. 1.

The MOS transistor 10 is a unipolar device. That is the MOS transistor 10 only comprises an electrical current carrier that works as conductive intermedium. Hence, the working speed of the MOS transistor 10 is slower than that of a bipolar device and the MOS transistors 10 neither gains current nor functions as a rectifier. If the MOS transistor 10 that only functions as a switch is employed as every MOS transistor of integrated circuits, it will increase number of the devices of integrated circuits and lower integration of integrated circuits. In addition, the gate oxide layer 30 of the MOS transistor 10 does not has good ability to tolerate high voltage owing to using the dry oxidation method to form the gate oxide layer 30. This easily brings about breakdown and further reduces reliability and lifetime of the MOS transistor 10.

### SUMMARY OF THE INVENTION

It is therefore a primary objective of the present invention to provide a MOS transistor that functions as a rectifier and employs silicon nitride as a dielectric layer of the MOS transistor for enhancing integration of the integrated circuits and reliability and lifetime of the MOS transistor.

In a preferred embodiment, the present invention provides a MOS transistor that functions as a rectifier positioned on a semiconductor wafer. The semiconductor wafer comprises a substrate, an active area defined on the substrate, a second P-type well positioned on the active area of the substrate and a field oxide layer positioned on the substrate which surrounds the active area. The MOS transistor comprises an N-type well positioned within a first predetermined area of the active area, a first P-type well positioned within the N-type well, a first N-type doped region positioned within the first P-type well, a second N-type doped region positioned within a second predetermined area of the active area, the second predetermined area not overlapping the first predetermined area, and a gate layer positioned on the substrate between the first N-type doped region and the second N-type doped region. The first N-type doped region and the second N-type doped region are separately used as a source and a drain of the MOS transistor. The gate layer comprises a gate dielectric layer positioned on the substrate and a gate electrode positioned on the gate dielectric layer.

It is an advantage of the present invention that the MOS transistor comprises the first P-type well and the N-type well which integrate with the second P-type well to form a bipolar junction transistor (BJT) Therefore, the MOS transistor functions as not only a switch but also a rectifier and this can increase integration of the integrated circuits. In addition, the gate dielectric layer possesses better ability to resist high pressure for preventing breakdown. Hence, the reliability and lifetime of the MOS transistor is enhanced.

This and other objective of the present invention will no doubt become obvious to those of ordinary skill in the art after having read the following detailed description of the preferred embodiment which is illustrated in the various figures and drawings.

### BRIEF DESCRIPTION OF THE DRAWINGS

FIG. 1 is a cross-sectional diagram of a structure of a MOS transistor according to the prior art.

FIG. 2 to FIG. 5 are schematic diagrams of a method of forming the MOS transistor shown in FIG. 1.

FIG. 6 is a cross-sectional diagram of a MOS transistor according to the present invention.

FIG. 7 to FIG. 12 are schematic diagrams of a method of forming the MOS transistor shown in FIG. 6.

FIG. 13 is a cross-sectional diagram of the MOS transistor shown in FIG. 6 formed on another semiconductor wafer.

FIG. 14 is a cross-sectional diagram of a MOS transistor according to another embodiment of the present invention.

### DETAILED DESCRIPTION OF THE PREFERRED EMBODIMENT

Please refer to FIG. 6. FIG. 6 is a cross-sectional diagram of a MOS transistor 40 according to the present invention. The MOS transistor 40 of the present invention is formed on a semiconductor wafer 42 and which functions as a rectifier. The semiconductor wafer 42 comprises a substrate 44, an active area 48 defined on the substrate 44, a P-type well 46 positioned on the active area of the substrate 44, and a field oxide layer 50 positioned on the substrate 44 which surrounds the active area 48. Furthermore, a N-type doped region 52 positioned within the P-type well 46 is used as a pick-up for grounding the P-type well 46.

The MOS transistor 40 comprises a N-type well 54 positioned within a predetermined area of the active area 48, a P-type well 56 positioned within the N-type well 54, a N-type doped region 58 positioned within the P-type well 56, a N-type doped region 60 positioned within another predetermined area of the active area 48, and a gate layer 62 positioned on the substrate 44 between the N-type doped regions 58′ 60. The N-type well 54 does not overlap the N-type doped region 60. The N-type doped regions 58′ 60 are separately used as a drain and a source of the MOS transistor 40. The gate layer 62 comprises a gate dielectric layer 64 made of silicon nitride positioned on the substrate 44 and a doped polysilicon layer 66 positioned on the gate dielectric layer 64 which is used as a gate electrode.

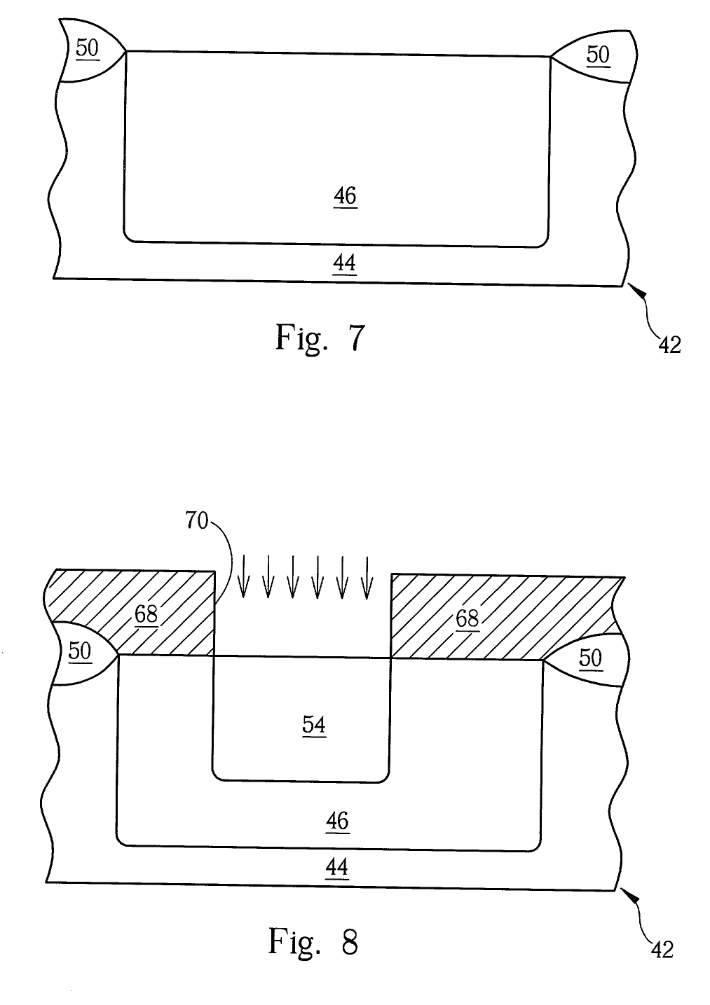

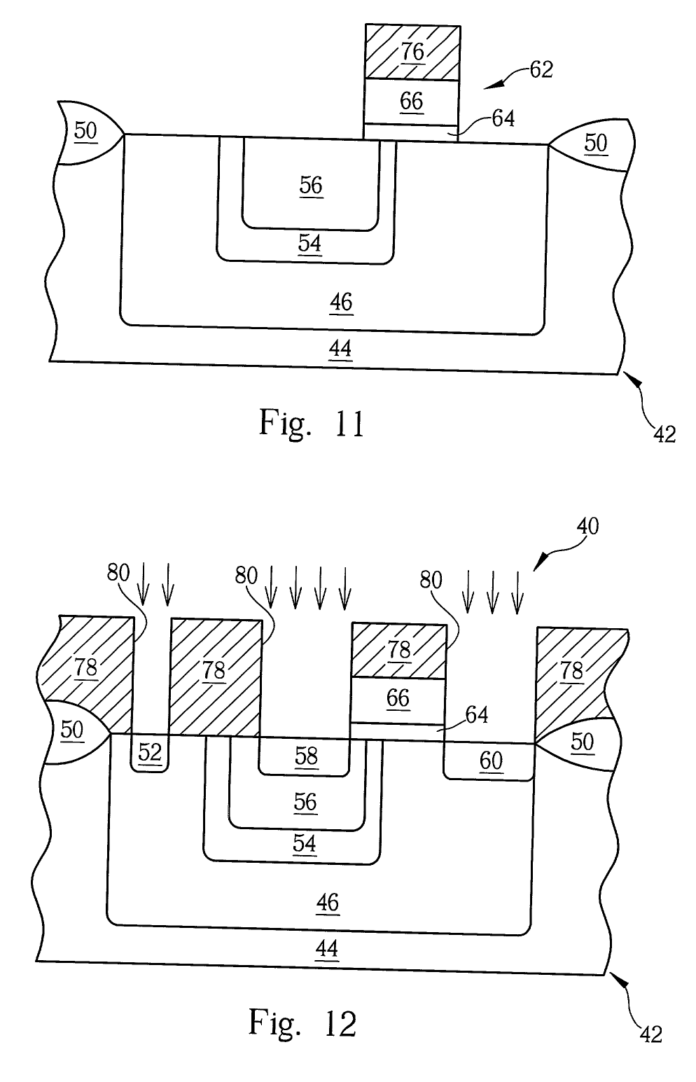

Please refer to FIG. 7 to FIG. 12. FIG. 7 to FIG. 12 are schematic diagrams of a method of forming the MOS transistor 40 shown in FIG. 6. As shown in FIG. 7, the semiconductor wafer 42 is used for forming the MOS transistor 40. As shown in FIG. 8, a photoresist layer 68 which comprises an opening 70 for defining the position of the N-type well 54 is firstly formed on the semiconductor wafer 42. An ion implantation process is then performed to form the N-type well 54 within the P-type well 46.

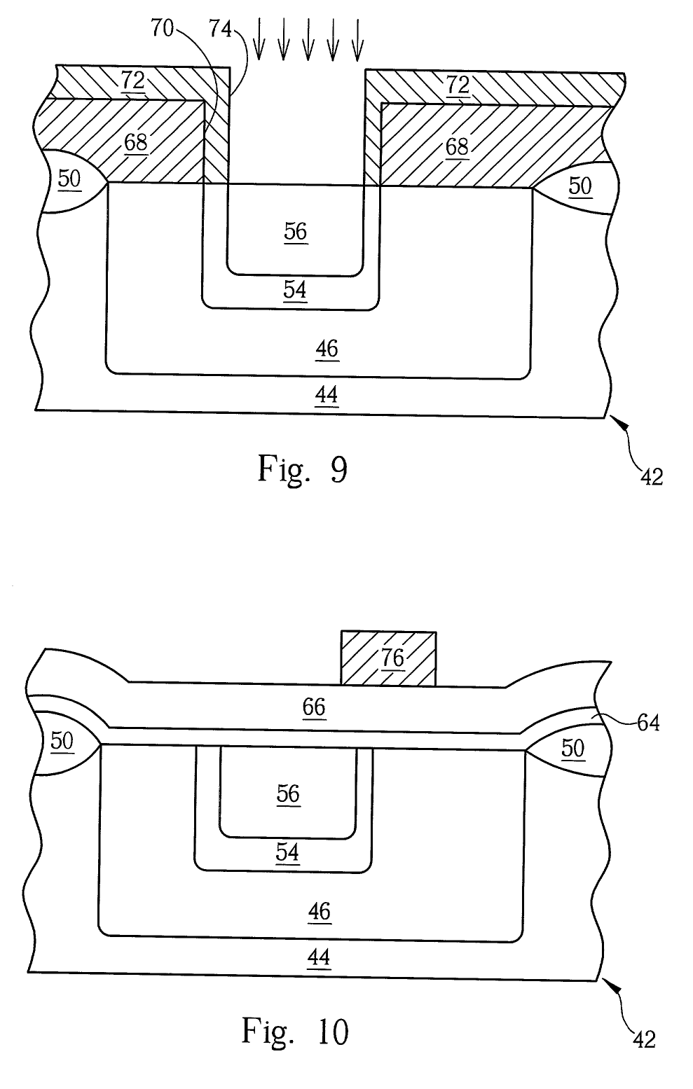

Next, as shown in FIG. 9, a photoresist layer 72 which comprises an opening 74 for defining the position of the P-type well 56 is formed on the photoresist layer 68 wherein the size of the opening 74 is smaller than that of the opening 70. An ion implantation process is then performed to form the P-type well 56 within the N-type well 54. After the photoresist layers 68′ 70 are removed, as shown in FIG. 10, a chemical vapor deposition (CVD) process is performed to sequentially deposit the gate dielectric layer 64 and the doped polysilicon layer 66 on the semiconductor wafer 42. Then, a photoresist layer 76 is formed on the doped polysilicon layer 66 for defining the position of the gate layer 62.

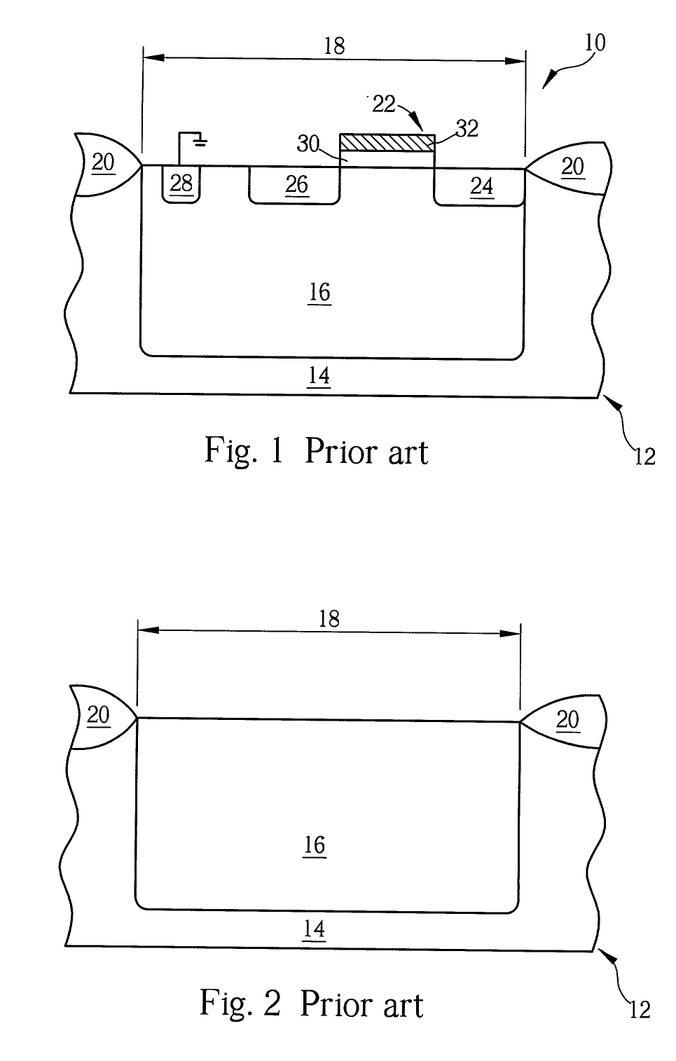

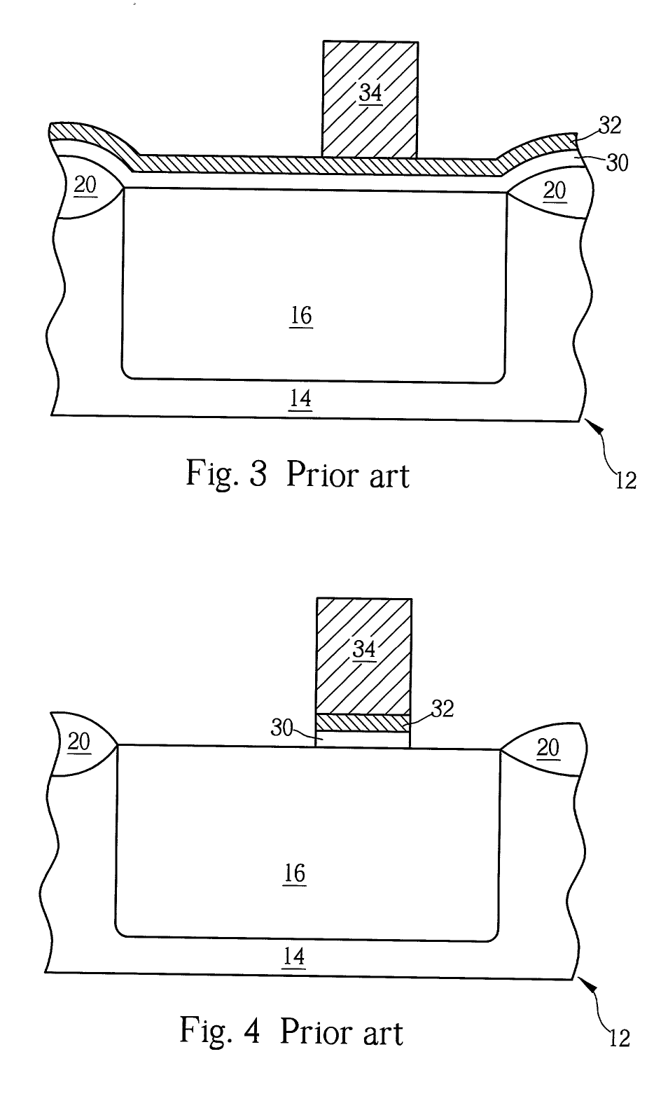

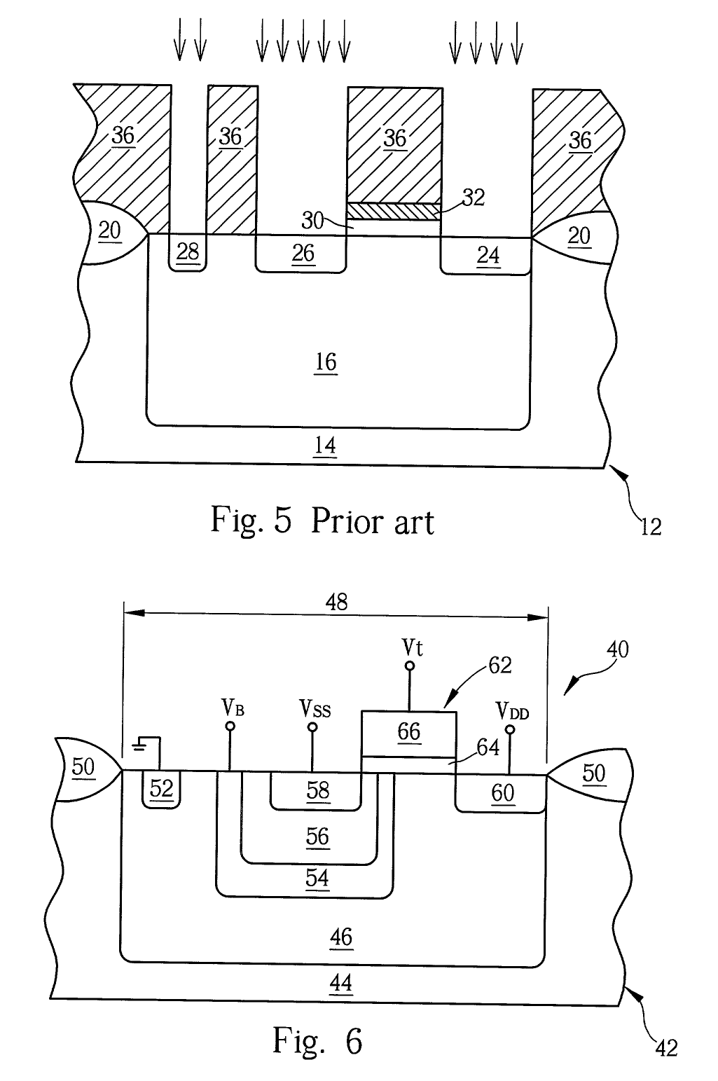

As shown in FIG. 1, an etching process is then performed to remove the gate dielectric layer 64 and the doped polysilicon layer 66 not covered by the photoresist layer 76. Next, the photoresist layer 76 is removed and thus completes the gate layer 62.

As shown in FIG. 12, a photoresist layer 78 is then formed on the semiconductor wafer 42 wherein the photoresist layer 78 comprises three openings 80 for separately defining the positions of the N-type doped regions 52′ 58′ 60. Next, an ion implantation process is performed to implant N-type dopants into the P-type well 46 so as to form the N-type doped regions 52′ 58′ 60 which are separately used as the well pick up, the drain and the source. Finally, the photoresist layer 78 is removed so as to complete the MOS transistor 40 as shown in FIG.6.

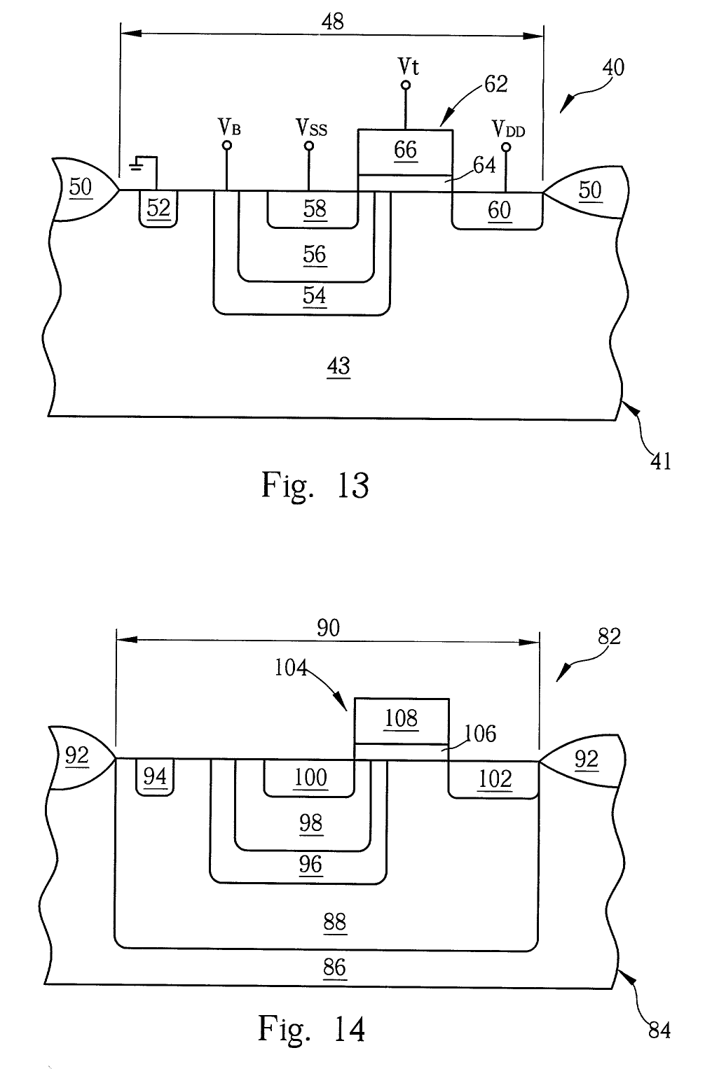

In addition, the MOS transistor 40 can be formed on another semiconductor wafer 41. As shown in FIG. 13, FIG. 13 is a cross-sectional diagram of the MOS transistor 40 formed on the semiconductor wafer 41. The semiconductor wafer 41 comprises a P-type substrate 43, the active area 48 defined on the P-type substrate 43, the N-type doped region 52 positioned within the active area 48, and the field oxide layers 50 positioned on the P-type substrate 43 which surrounds the active area 48. The N-type doped region 52 is used as a pick-up for grounding the P-type substrate 43.

Please refer to FIG. 14. FIG. 14 is a cross-sectional diagram of a MOS transistor 82 according to another embodiment of the present invention. The MOS transistor 82 is formed on a semiconductor wafer 84. The semiconductor wafer 84 comprises a substrate 86, an active area 90 defined on the substrate 86, a N-type well 88 positioned within the substrate 86 of the active area 90, and a field oxide 92 positioned on the substrate 86 which surrounds the active area 90. The semiconductor wafer 84 further comprises a P-type doped region 94 positioned on the active area 90 which is used as a well pick-up for grounding the N-type well 88. In addition, the MOS transistor 82 can be formed on another semiconductor wafer (not shown) which is almost the same as the semiconductor wafer 84 except for employing a N-type substrate but not utilizing any N-type well.

The MOS transistor 82 comprises a P-type well 96 positioned on a first predetermined area of the active area 90, a N-type well 98 positioned within the P-type well 96, a P-type doped region 100 positioned within the N-type well 98, a P-type doped region 102 positioned on a second predetermined area of the active area 90, and a gate layer 104 positioned on the substrate 86 between the P-type doped regions 100′ 102. The first predetermined area and the second predetermined area are not positioned to overlap each other. The P-type doped regions 100′ 102 are separately used as a drain and a source of the MOS transistor 82. The gate layer 104 comprises a gate dielectric layer 106 made of silicon nitride positioned on the substrate 86 and a doped polysilicon layer 108 positioned on the gate dielectric layer 106 which is used as a gate electrode.

According to the above mention of the present invention, the MOS transistor 40 comprises the N-type well 54 and the P-type well 56 which integrate with the P-type well 46 to form a bipolar junction transistor (BJT) in the channel under the gate layer 62. The BJT can be used as an amplifier between the drain and the source. When gate voltage (Vₜ) is smaller than threshold voltage of the MOS transistor 40, the P-type well 56, the N-type well 54 and the P-type well 46 form a PNP BJT. When gate voltage (Vₜ) is larger than threshold voltage of the MOS transistor 40 and base voltage (V_{B}) is larger than gate voltage (Vₜ), the channel under the gate layer 62 is in an inversion state so as to form the P-type well 56, the N-type well 54 and the P-type well 46 as a NPN BJT. As well, the MOS transistor 82 comprises a NPN BJT or PNP BJT formed under the gate layer 104 which acts the part of current gain. Consequently, each of the MOS transistors 40′ 82 not only can function as a switch but also a rectifier. Furthermore, the PNP BJT or NPN BJT is a bipolar device, which utilizes electrons and holes to conduct electrical current at the same time. This can enhances the working speed of the MOS transistors 40′ 82.

The gate dielectric layers 64′ 106 of the MOS transistors 40′ 82 are formed by the CVD process to deposit silicon nitride. Because the process temperature of the CVD process is lower, thermal budget of the present invention is reduced and the dopants in the semiconductor wafers 42′ 84 are not easily diffused due to heating. Therefore, each width of the N-type well 54 and P-type well 96 is exactly controlled. This can reduce the width of the base of the BJT and enhance the effect of current gain. Though the order of leakage current of silicon nitride is the same as that of silicon oxide, the gate dielectric layers 64 106 made of silicon nitride possesses better ability to tolerate high pressure. This can promotes reliability of the MOS transistors 40′ 82.

In addition, the present invention employs the CVD process to form the gate dielectric layers 64′ 106 after the N-type wells 54′ 98 and the P-type wells 56′ 96 are completed by the ion implantation process. This can form the gate dielectric layers 64′ 106 of uniform thickness. Compare with the prior method of forming the gate dielectric layer by the thermal oxidation process, growing speed of the silicon oxide is not all the same according to the difference in doped density of the substrate. This forms the gate dielectric layer of uneven thickness and which easily brings about breakdown and reduces reliability of the MOS transistor. Whereas, the present invention can solve the above-mentioned problem and prolong lifetime of the MOS transistors 40′ 82.

Compared to the prior art of the MOS transistor 10 which only functions as a switch, in the MOS transistor 40 of the present invention, the P-type well 56 and the N-type well 54 can integrate with the P-type well 46 to form the BJT. Likewise, in the MOS transistor 82 of the present invention, the N-type well 98, the P-type well 96 and the N-type well 88 can form the BJT. Hence, the MOS transistors 40′ 82 not only function as switches but also function as rectifiers. This can increase integration of integrated circuits. In addition, the present invention employs the CVD method to form the gate dielectric layers 64′ 106 made of silicon nitride, so thermal budget is reduced and ability of tolerating high pressure is improved. As a result, it is difficult to appear breakdown phenomenon and the reliability and lifetime of the MOS transistors 40′ 82 are enhanced.

Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A metal-oxide semiconductor (MOS) transistor that functions as a rectifier positioned on a semiconductor wafer, the semiconductor wafer comprising a substrate, an active area defined on the substrate, and an insulating layer positioned on the substrate which surrounds the active area, the MOS transistor comprising:
an N-type well positioned within a first predetermined area of the active area;
a first P-type well positioned within the N-type well;
a first N-type doped region positioned within the first P-type well;
a second N-type doped region positioned within a second predetermined area of the active area, the second predetermined area not overlapping the first predetermined area; and
a gate layer positioned on the substrate between the first N-type doped region and the second N-type doped region;
wherein the first N-type doped region and the second N-type doped region are separately used as a source and a drain of the MOS transistor.

2. The MOS transistor of claim 1 wherein the substrate is a P-type substrate.

3. The MOS transistor of claim 2 wherein the active area further comprises a third N-type doped region which is used as a pick-up for grounding the P-type substrate.

4. The MOS transistor of claim 1 wherein the substrate further comprises a second P-type well and the active area is defined above the second P-type well.

5. The MOS transistor of claim 4 wherein the active area further comprises a fourth N-type doped region which is used as a well pick-up for grounding the second P-type well.

6. The MOS transistor of claim 1 where in the insulating layer comprises a field oxide layer.

7. The MOS transistor of claim 1 wherein the gate layer comprises a gate dielectric layer positioned on the substrate and a gate electrode positioned on the gate dielectric layer.

8. The MOS transistor of claim 7 wherein the gate dielectric layer is made of a silicon-nitride compound.

9. The MOS transistor of claim 7 wherein the gate electrode is a doped polysilicon layer.

10. A metal-oxide semiconductor (MOS) transistor that functions as a rectifier positioned on a semiconductor wafer, the semiconductor wafer comprising a substrate, an active area defined on the substrate, and an insulating layer positioned on the substrate which surrounds the active area, the MOS transistor comprising:
a P-type well positioned within a first predetermined area of the active area;
a first N-type well positioned within the P-type well;
a first P-type doped region positioned within the first N-type well;
a second P-type doped region positioned within a second predetermined area of the active area, the second predetermined area not overlapping the first predetermined area; and
a gate layer positioned on the substrate between the first P-type doped region and the second P-type doped region;
wherein the first P-type doped region and the second P-type doped region are separately used as a source and a drain of the MOS transistor.

11. The MOS transistor of claim 10 wherein the substrate is an N-type substrate.

12. The MOS transistor of claim 11 wherein the active area further comprises a third P-type doped region which is used as a pick-up for grounding the N-type substrate.

13. The MOS transistor of claim 10 wherein the substrate further comprises a second N-type well and the active area is defined above the second N-type well.

14. The MOS transistor of claim 13 wherein the active area further comprises a fourth P-type doped region which is used as a well pick-up for grounding the second N-type well.

15. The MOS transistor of claim 10 wherein the insulating layer is a field oxide layer.

16. The MOS transistor of claim 10 wherein the gate layer comprises a gate dielectric layer positioned on the substrate and a gate electrode positioned on the gate dielectric layer.

17. The MOS transistor of claim 16 wherein the gate dielectric layer is made of a silicon-nitride compound.

18. The MOS transistor of claim 16 wherein the gate electrode is a doped polysilicon layer. positioned on the gate dielectric layer.
